(19) United States
(12) Patent Application Publication
(10) Pub. No.: US 2005/0230734 A1
(43) Pub. Date: Oct. 20, 2005

(54) Field effect transistors having trench-based gate electrodes and methods of forming same

(76) Inventors: Jae-Kyu Ha, Gyeonggi-do (KR); Jong-Chul Park, Gyeonggi-do (KR)

Correspondence Address: MYERS BIGEL SIBLEY & SAJOVEC, PO BOX 37428, RALEIGH, NC, 27627, US

(21) Appl. No.: 11/109,422

(22) Filed: Apr. 19, 2005

(30) Foreign Application Priority Data
Apr. 20, 2004 (KR) 2004-26961

(51) Int. Cl. H01L 27/108

(52) U.S. Cl. 257/306

(57) ABSTRACT

Embodiments of the invention include dynamic random access memory (DRAM) devices that utilize field effect transistors with trench-based gate electrodes. In these devices, a semiconductor substrate is provided having an isolation trench therein. This isolation trench is formed in a first portion of the semiconductor substrate. An electrically insulating liner is provided on a bottom and sidewalls of the isolation trench. The isolation trench is also filled with field oxide region, which extends on the electrically insulating liner. A field effect transistor is also provided in the semiconductor substrate. This transistor includes a gate electrode trench in a second portion of the semiconductor substrate and a gate insulating layer that lines a bottom and sidewalls of the gate electrode trench. A gate electrode is provided in the gate electrode trench. The gate electrode contacts the electrically insulating liner in the isolation trench and the gate insulating layer. Source and drain regions extend in the semiconductor substrate and adjacent the gate electrode.

### CROSS REFERENCE TO RELATED APPLICATION

This application claims priority under 35 USC § 119 to Korean Patent Application No. 2004-26961, filed on Apr. 20, 2004, the contents of which are hereby incorporated herein by reference.

### FIELD OF THE INVENTION

The present invention relates to integrated circuit devices and methods of forming same and, more particularly, to field effect transistors and methods of forming field effect transistors.

### BACKGROUND OF THE INVENTION

As a semiconductor device has been highly integrated, a size of an active region in the semiconductor device has been reduced. Thus, a channel region of a MOS transistor formed in the active region typically has a length on a sub-micron scale. When the length of the channel region is shortened, source/drain regions in the MOS transistor greatly influence an electric effect on depletion layers adjacent to the source/drain regions. This is referred to as a short channel effect. An example of the short channel effect includes decrease in threshold voltage Vt. The decrease in the threshold voltage occurs due to a great influence on the channel region from electrons, an electric field and an electric potential distribution in the depletion layers as well as a voltage applied to a gate electrode of the MOS transistor due to a shortening of the length of the channel region. Another example of the short channel effect includes a decrease in the breakdown voltage between the source/drain regions. The depletion layer adjacent to the drain region is widened proportional to increase in a drain voltage so that the depletion layer adjacent to the drain region is closely disposed to the depletion layer adjacent to the source region. As a result, when the length of the channel region is shortened, the depletion layer adjacent to the drain region is readily formed to be connected to the depletion layer adjacent to the source region.

In the above state, since an electric field in the drain region has an influence on the source region, an electric potential for diffusing electrons in the source region is lowered. Thus, although the channel region is not formed between the source/drain regions, a current flows between the source/drain regions. This is referred to as punch-through. When punch-through occurs, a current flowing through the drain region is remarkably increased without being saturated in a saturated region.

Meanwhile, to increase memory capacity of a semiconductor device, particularly in a dynamic random access memory (DRAM) device, forming unit cells in a small area is required. However, since a capacitance of a capacitor in the cell is maintained at a predetermined level, the length of the gate electrode is shortened to form a highly integrated cell. The length of the channel region is shortened proportional to shortening the length of the gate electrode so that the short channel effect occurs, thereby generating the decrease of the threshold voltage and the increase of the leakage current. Furthermore, as the cell has been highly integrated, the adjacent gate electrodes are closely arranged from each other. Thus, forming a minute contact between the adjacent gate electrodes is very difficult, thereby generating a closed state of a contact hole and an inferior resistance of the contact.

To prevent the short channel effect and also to improve characteristics of refreshing a transistor, a conventional transistor having a recessed channel has been studied. The transistor has a lengthened length of a gate electrode without increasing a horizontal area of the gate electrode due to the recessed channel. The transistor includes the gate electrode formed in a trench for the gate electrode that is formed at a surface portion of a substrate. The recessed channel is formed along an inner wall and a bottom face of the trench for the gate electrode. Here, a field insulation layer pattern is preferably exposed through an inner wall portion of the trench for the gate electrode except an inner wall portion of the trench for the gate electrode corresponding to source/drain regions.

However, a trench for forming the field insulation layer pattern and the trench for the gate electrode are formed by an anisotropic etching process so that the trenches have an upper width and a lower width less than the upper width. Namely, the trenches have sloped profiles having gradually widened widths in an upward direction. As a result, the trenches have the sloped profiles inclined in opposite directions, respectively, so that a portion of the silicon substrate between the field insulation layer pattern and a sidewall of the trench for the gate electrode may partially remain, thereby forming a silicon fence between the field insulation layer pattern and the sidewall of the trench for the gate electrode. Thus, a parasitic channel may be formed along the silicon fence so that the conventional transistor may not have an increased length of the channel region, thereby deteriorating electrical characteristics of the conventional transistor.

### SUMMARY OF THE INVENTION

Embodiments of the invention include dynamic random access memory (DRAM) devices that utilize field effect transistors with trench-based gate electrodes. In these devices, a semiconductor substrate is provided having an isolation trench therein. This isolation trench is formed in a first portion of the semiconductor substrate. An electrically insulating liner is provided on a bottom and sidewalls of the isolation trench. The isolation trench is also filled with field oxide region, which extends on the electrically insulating liner. A field effect transistor is also provided in the semiconductor substrate. This transistor includes a gate electrode trench in a second portion of the semiconductor substrate and a gate insulating layer that lines a bottom and sidewalls of the gate electrode trench. A gate electrode is provided in the gate electrode trench. The gate electrode contacts the electrically insulating liner in the isolation trench and the gate insulating layer. Source and drain regions extend in the semiconductor substrate and adjacent the gate electrode.

A semiconductor device in accordance with another embodiment of the present invention includes a substrate divided into an active region and a field region. A field oxide layer fills up an isolation trench that is formed at a surface portion of the substrate. A gate trench is formed in the active region. The gate trench exposes an interface between the active region and the field region and has a bottom face and an opened top face wider than the bottom face. An insulation liner includes a first portion that is formed on a side face and a bottom face of the isolation trench and has a first upper end positioned on a plane substantially identical to the surface of the substrate, and a second portion that is formed on a side face and a bottom face of the gate trench and has a second upper end lower than the surface of the substrate. A gate electrode is formed on the substrate and in the gate trench. Source/drain regions are formed at both sides of the gate electrode. According to this embodiment, the gate electrode may include a linear gate electrode. The linear gate electrode comprises a plurality of linear gate electrodes. The linear gate electrodes are disposed in a single active region. A capacitor is electrically connected to at least one of the source/drain regions.

In a method of forming a recessed gate electrode in accordance with another embodiment of the present invention, a field region including an isolation trench, an insulation liner having an upper end lower than a surface of a substrate, and a field oxide layer filling up the isolation trench is formed in the substrate to define an active region of the substrate. A gate trench is formed in the active region. The gate trench exposes an interface between the active region and the field region and has a bottom face and an opened top face wider than the bottom face. A gate electrode is then formed on the substrate and in the gate trench.

In a method of forming a semiconductor device in accordance with still another embodiment of the present invention, a field region partially exposing a side upper portion of an active region at an interface between the active region and the field region is formed in a substrate to define the active region in the substrate. A portion of the active region including the exposed side upper portion is partially etched to form a gate trench exposing the interface between the active region and the field region. A gate electrode is formed on the substrate and in the gate trench. Source/drain regions are then formed in portions of the active region at both sides of the gate electrode.

In a method of manufacturing a semiconductor device in accordance with still another embodiment of the present invention, an isolation trench is formed at a surface portion of a substrate. A preliminary insulation liner is formed on a side face and a bottom face of the isolation trench. The isolation trench is filled with a field oxide layer to define an active region in the substrate. A hard mask pattern is formed in the active region. The hard mask pattern selectively exposes a region in which a gate electrode is formed and a portion of the preliminary insulation liner making contact with the region. The preliminary insulation liner is partially etched using the hard mask pattern as an etching mask to form an insulation liner having an upper end lower than the surface of the substrate. The substrate is etched using the hard mask pattern and the insulation line as an etching mask to form a gate trench. A gate electrode is formed on the substrate and in the gate trench. Source/drain regions are then formed in the active region at both sides of the gate electrode.

According to the present invention, the etching process for forming the gate trench is performed in condition that the side face of the active region as well as the upper face of the active region is exposed, thereby suppressing formation of a silicon fence at the interface between the gate trench and the field region. Thus, a parasitic channel in the silicon fence may be reduced.

### BRIEF DESCRIPTION OF THE DRAWINGS

The above and other features and advantages of the invention will become readily apparent by reference to the following detailed description when considered in conjunction with the accompanying drawings wherein:

FIG. 1 is a plan view illustrating a DRAM device having a recessed gate electrode in accordance with a first embodiment of the present invention;

FIG. 2 is a cross sectional view taken along line 2-2′ in FIG. 1;

FIG. 3 is a cross sectional view taken along line 3-3′ in FIG. 1;

FIGS. 4 to 18 are cross sectional views illustrating a method of manufacturing the DRAM device in FIGS. 1 to 3;

FIGS. 19 and 20 are plan views illustrating a method of manufacturing the DRAM device in FIGS. 1 to 3; and

FIGS. 21 and 22 are cross sectional views illustrating a method of manufacturing the DRAM device in FIGS. 1 to 3 in accordance with a second embodiment of the present invention.

### DESCRIPTION OF THE EMBODIMENTS

The present invention now will be described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. In the drawings, the thickness of layers and regions are exaggerated for clarity. Like reference numerals refer to similar or identical elements throughout. It will be understood that when an element such as a layer, a region or a substrate is referred to as being “on” or “onto” another element, it can be directly on the other element or intervening elements may also be present.

Hereinafter, a semiconductor device, a method of forming a gate electrode and a method of manufacturing the semiconductor device in accordance with preferred embodiments of the present invention are illustrated in detail.

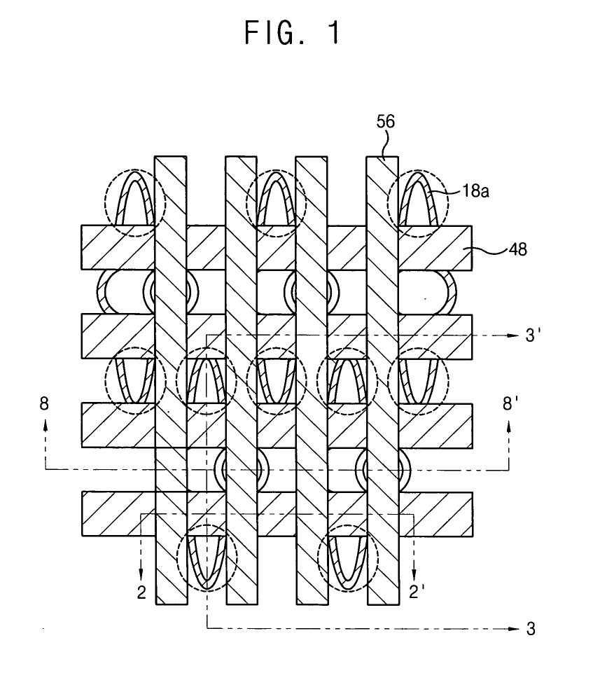

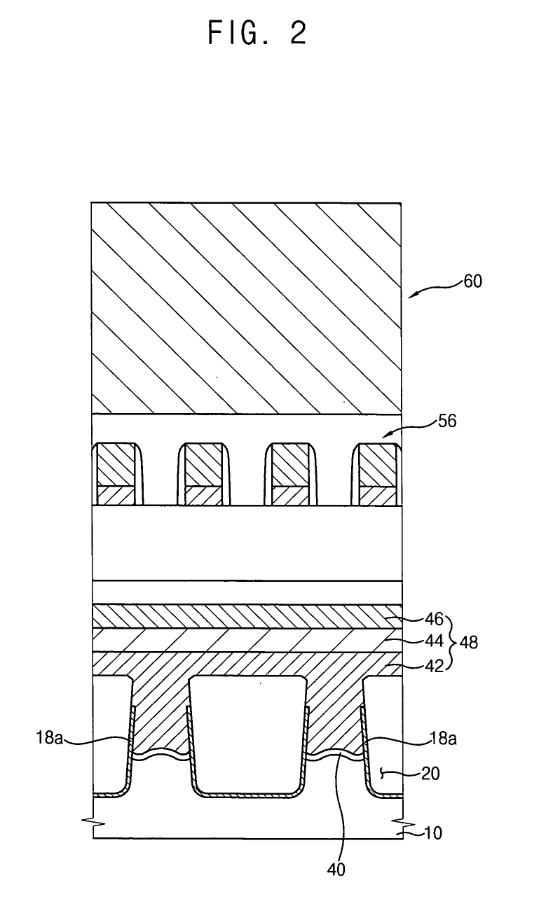

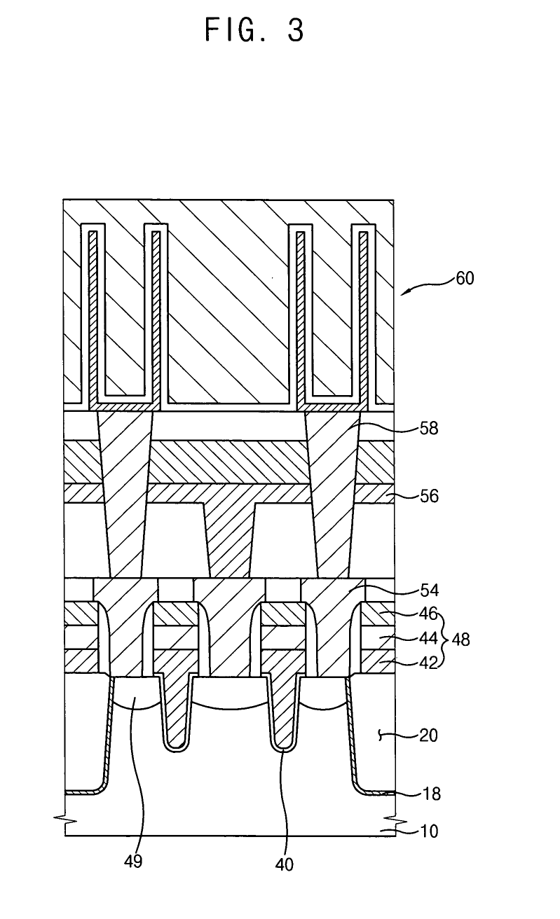

FIG. 1 is a plan view illustrating a DRAM device having a recessed gate electrode in accordance with a first embodiment of the present invention, FIG. 2 is a cross sectional view taken along line 1-1′ in FIG. 1 and FIG. 3 is a cross sectional view taken along line 2-2′ in FIG. 1. Referring to FIGS. 1 to 3, a semiconductor substrate 10 is divided into a field region and an active region. The field region is formed by an isolation process. In particular, the field region includes an isolation trench for defining the field region, an insulation liner 18a formed on a side face and a bottom face of the isolation trench, and a field oxide layer 20 formed on the insulation liner 18a to fill up the isolation trench. The side face of the isolation trench has a sloped shape so that the isolation trench has an opened top face wider than the bottom face. The insulation liner 18a is formed at an interface between the field oxide layer 20 and the semiconductor substrate 10. For an example, the insulation layer liner 18a may be formed using a material having an etching selectivity with respect to the field oxide layer 20 such as silicon nitride. Also, the insulation liner 18a is partially recessed from an interface between an upper face of the active region corresponding to a region in which a gate electrode is formed, and an upper face of the field oxide layer 20 by a predetermined thickness.

A gate trench is formed in a portion of the active region at which the gate electrode is formed. When the gate electrode is used for a DRAM device, two gate electrodes are formed in a single active region so that two gate trenches are required. The interface between the active region and the field region is partially exposed from side faces of the gate trenches. Particularly, an upper face of the field region is exposed through both side faces of the gate trenches. The gate trench positioned at the interface between the active region and the field region has an opened top face wider than a bottom face due to the recessed insulation liner 18a. That is, since the insulation liner 18a is partially recessed by the predetermined thickness, the upper face of the gate trench is widened by the recessed thickness of the insulation liner 18a. Also, a bottom face of the gate trench has a protruded central portion and an edge portion.

Particularly, the insulation liner 18a includes a first portion that is formed on a side face and a bottom face of the isolation trench and has a first upper end positioned on a plane substantially identical to the surface of the substrate 10, and a second portion that is formed on a side face and a bottom face of the gate trench and has a second upper end lower than the surface of the substrate 10.

A gate insulation layer 40 is formed on the insulation liner 18a. A gate electrode 48 is formed on the semiconductor substrate 10 to fill up the gate trench. The gate electrode 48 is a lane shape substantially perpendicular to a length direction of the active region. Also, since the bottom face of the gate trench has the protruded central portion, a bottom face of the gate electrode 48 has a protruded central portion.

Source/drain regions 49 are formed in the active region at both sides of the gate electrode 48. The source/drain regions 49 have a bottom face higher than that of the gate trench. Here, the source region is referred to as a bit line contact region positioned at a central portion of the active region and the drain region is referred to as a region in which a capacitor is formed at edge portions of the active region. A contact pad 54 is electrically connected to the source/drain regions 49. A bit line 56 is electrically connected to the source/drain regions 49 and is disposed substantially perpendicular to the gate electrode 48. A capacitor 60 is electrically connected to the contact pad 54 that makes contact with the drain region. According to the present embodiment, the DRAM device includes the recessed transistor so that charges leaking from the capacitor 60 may not flow from the drain region to the source region. Thus, the DRAM device has a long data retention time, thereby improving refresh characteristics of the DRAM device. Also, a silicon fence may not be formed between the field region and the recessed transistor so that a channel leak may not be generated along the silicon fence. As a result, the DRAM device may have improved operation characteristics and reliability.

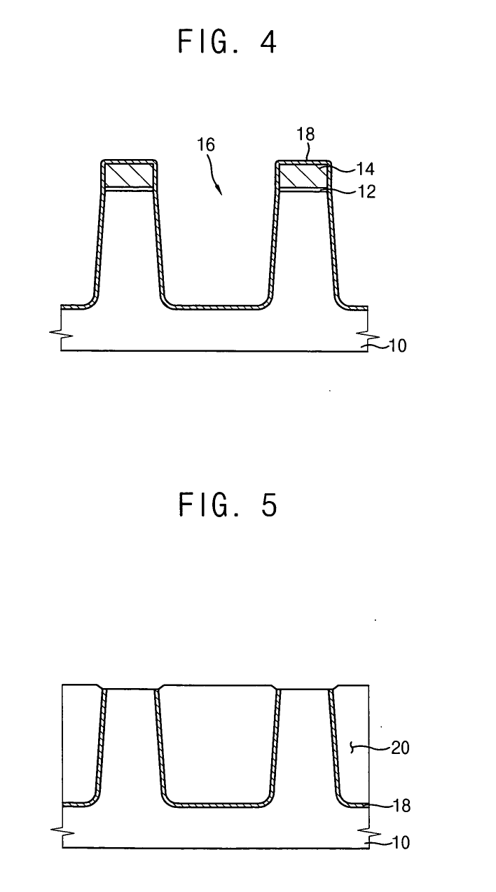

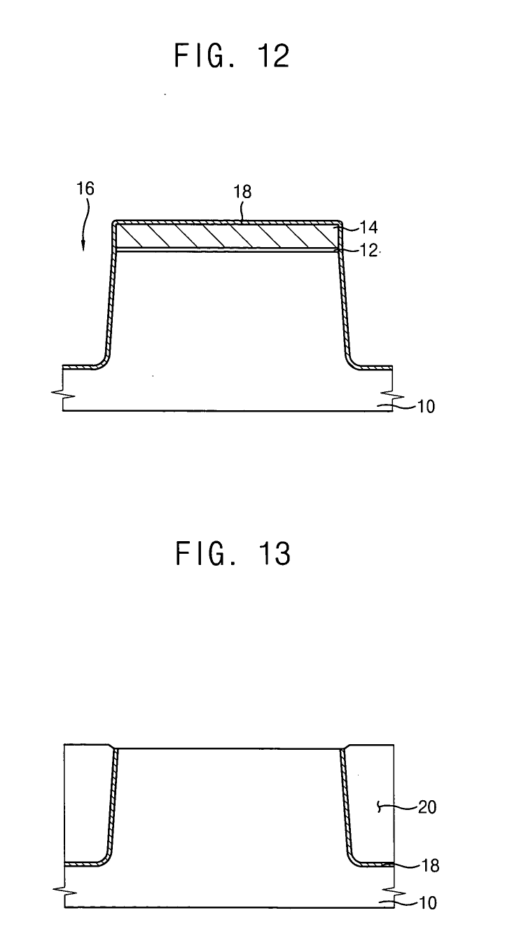

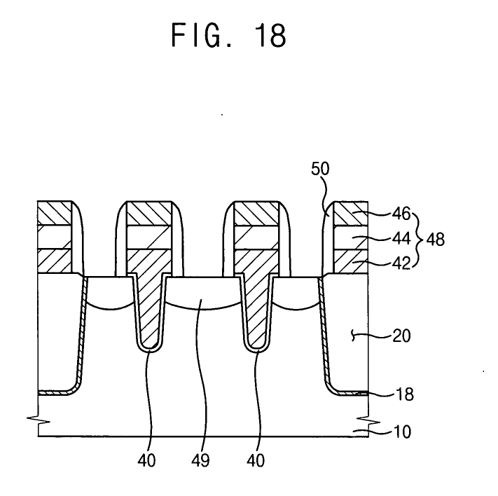

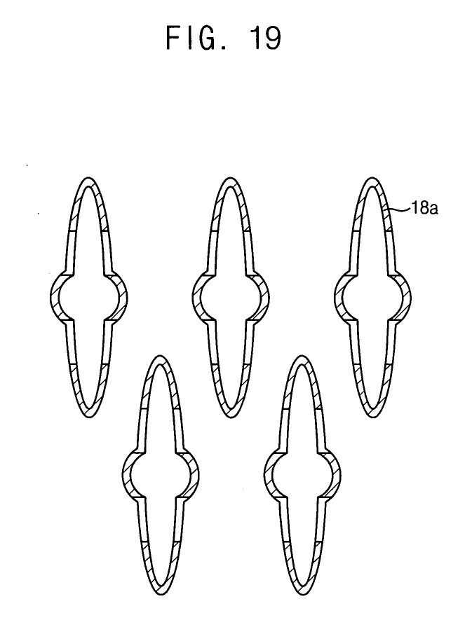

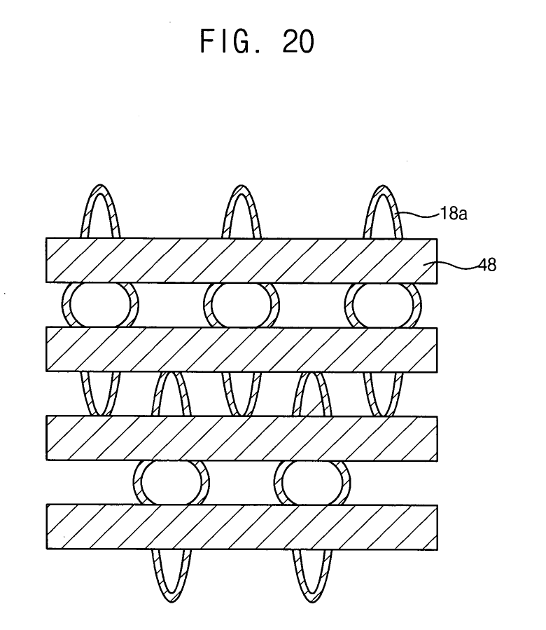

FIGS. 4 to 18 are cross sectional views illustrating a method of manufacturing the DRAM device in FIGS. 1 to 3 and FIGS. 19 and 20 are plan views illustrating a method of manufacturing the DRAM device in FIGS. 1 to 3. FIGS. 4 to 7 and FIGS. 9 to 11 are cross sectional views taken along line 2-2′ in FIG. 1, FIG. 8 is a cross sectional view taken along line 8-8′ in FIG. 1, and FIGS. 12 to 18 are cross sectional views taken along line 3-3′ in FIG. 1.

FIGS. 4, 5, 12 and 13 are views illustrating a process for forming a field region and an active region by a trench isolation process. Referring to FIGS. 4 and 12, a buffer oxide layer (not shown) and a first silicon nitride layer (not shown) are sequentially formed on a semiconductor substrate 10. The buffer oxide layer functions as to reduce stresses that are generated by directly contacting the first silicon nitride layer with the semiconductor substrate 10. Additionally, an anti-reflective layer (not shown) may be formed on the first nitride layer. The first silicon nitride layer is partially etched to form a first hard mask pattern 14 partially exposing the field region. The buffer oxide layer is dry-etched using the first hard mask pattern 14 as an etching mask to form a buffer oxide layer pattern 12. The semiconductor substrate 10 is dry-etched to form an isolation trench 16. The isolation trench 16 has an opened top face, a bottom face wider than the opened top face, and a sloped side face connected between the opened top face and the bottom face. To cure damages on surfaces of the semiconductor substrate 10 generated in the dry etching process, the semiconductor substrate 10 is thermally oxidized to form a thin thermal oxide layer (not shown) on the side face and the bottom face of the isolation trench 16. A preliminary insulation liner 18 having a thickness in the hundreds of angstroms is formed on the side face and the bottom face of the isolation trench 16, the buffer oxide layer pattern 12 and the first hard mask pattern 14. The preliminary insulation liner 18 serves for reducing stresses in a field oxide layer filling up the isolation trench 16 and also preventing impurities from diffusing into the field region. The preliminary insulation liner 18 may include a material having an etching selectivity higher than that of the field oxide layer. For an example, the preliminary insulation liner 18 may be formed using silicon nitride.

Referring to FIGS. 5 and 13, a silicon oxide layer (not shown) is formed on the preliminary insulation liner 18 to fill up the isolation trench 16. The silicon oxide layer, the first hard mask pattern 14 and the buffer oxide layer pattern 12 are removed by a chemical mechanical polishing (CMP) process to form the field oxide layer 20 defining the active region and the field region in the semiconductor substrate 10. The field oxide layer 20 has a trapezoidal cross section that includes a lower side and an upper side longer than the lower side. On the contrary, the active region defined by the field oxide layer 20 has a trapezoidal cross section that includes a lower side and an upper side shorter than the lower side.

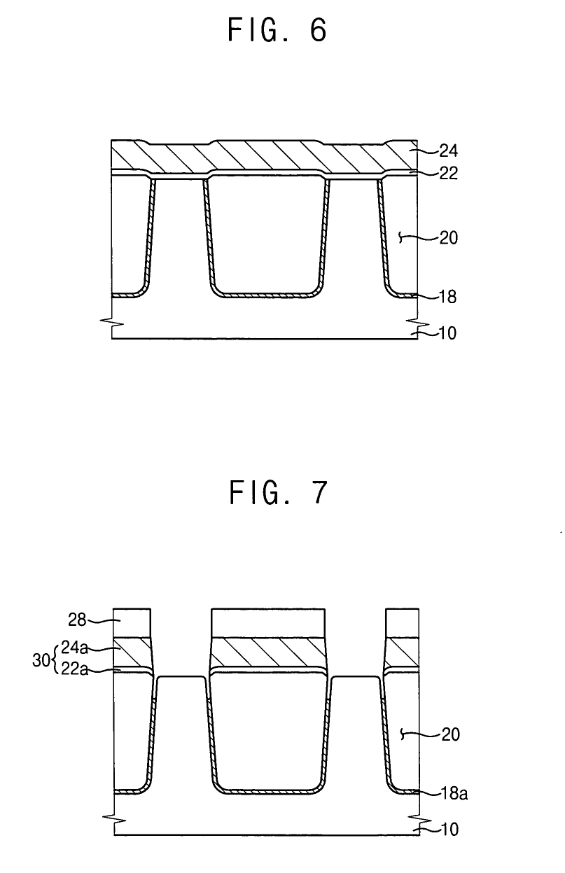

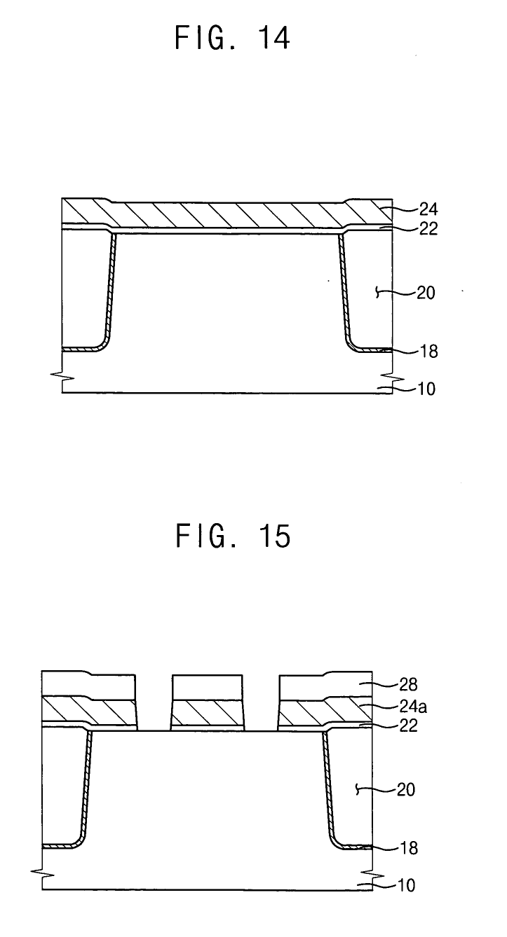

FIGS. 6 to 10 and FIGS. 14 to 19 are views illustrating a process for forming a gate trench. Referring to FIGS. 6 and 14, a middle temperature oxide (MTO) layer 22 as a pad oxide layer having a thickness of about 100 Å to about 500 Å is formed on the semiconductor substrate 10 at a temperature of about 700° C. to about 850° C. by a chemical vapor deposition (CVD) process. The MTO layer 22 serves for reducing stresses generated in forming a silicon oxynitride layer 24. The silicon oxynitride layer 24, which operates as a hard mask layer for forming a gate trench, is formed on the MTO layer 22. Additionally, an organic anti-reflective coating (not shown) may be formed on the silicon oxynitride layer 24.

Referring to FIGS. 7 and 15, a photoresist film (not shown) is formed on the silicon oxynitride layer 24. The photoresist film is patterned to form a first photoresist pattern 28. The silicon oxynitride layer 24 and the MTO layer 22 are dry-etched using the photoresist film as an etching mask to form a second hard mask pattern 30 including an MTO layer pattern 22a and a silicon oxynitride layer pattern 24a. Here, the second hard mask pattern 30 has an opening wider than that of the first photoresist pattern 28. A portion of the preliminary insulation liner 18 exposed through the MTO layer pattern 22a is partially etched to form a recessed insulation liner 18a. Here, forming second hard mask pattern 30 and etching the preliminary insulation liner 18 may be simultaneously carried out in one etching process. Also, etching the preliminary insulation liner 18 may be performed without changing etching gases. Meanwhile, a recessed depth of the insulation liner 18a may be preferably shallower than a depth of a gate trench.

Further, to remove a desired thickness of the preliminary insulation liner 18 by slightly over-etching the MTO layer 22, an etching speed with respect to the preliminary insulation liner 18 may be faster than that with respect to the MTO layer 22. In particular, an etching ratio between the MTO layer 22 and the preliminary insulation liner 18 is no less than about 1:3. To meet the above-mentioned etching conditions, etching the silicon oxynitride layer 24, the MTO layer 22 and the preliminary insulation liner 18 may be carried out using an etching gas mixed of CH₂F₂, CF₄, O₂, etc.

FIG. 8 is a cross sectional view taken along line 8-8′ in FIG. 1, which illustrates the active region at which the gate trench is not formed. FIG. 19 is a plan view illustrating a recessed portion of the insulation liner.

Referring to FIGS. 7, 8 and 19, the insulation liner 18a is partially recessed at a region in which the gate trench is formed. On the contrary, the insulation liner 18a is not recessed at a region in which the gate trench is not formed. Also, as shown in FIG. 15, the insulation liner 18a is not exposed through a side face of the gate trench that is not adjacent to the field region. In the present embodiment, configurations of the recessed insulation liner 18a are quite different from those of a conventional trench liner dent that causes process failures. According to the conventional trench liner dent, an entire upper portion of an insulation liner formed at an interface between an active region and a field region is dented so that a bridge connected between adjacent devices may be formed. On the contrary, according to the present embodiment, since the insulation liner 18a in the region 32 in which the gate electrode is formed is selectively recessed in FIGS. 7, 8 and 19, a bridge connected between adjacent devices may not be formed.

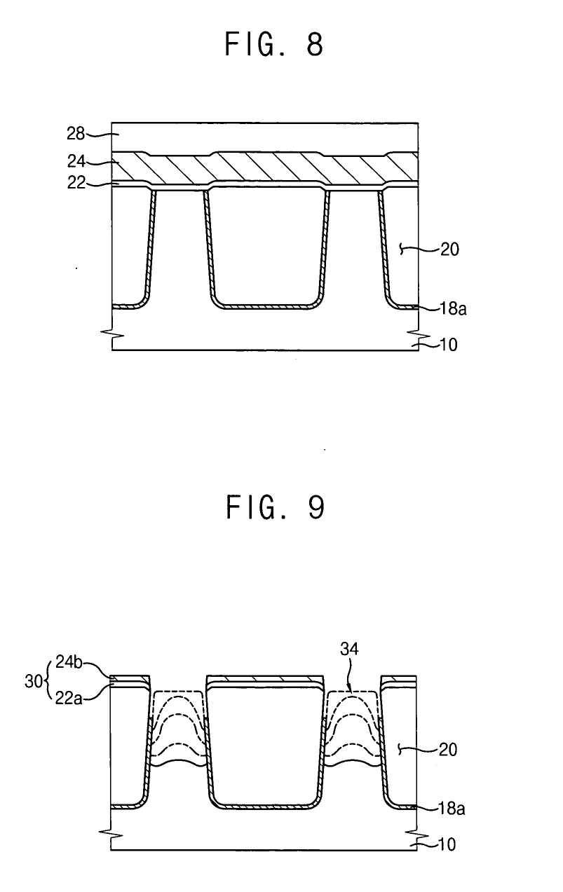

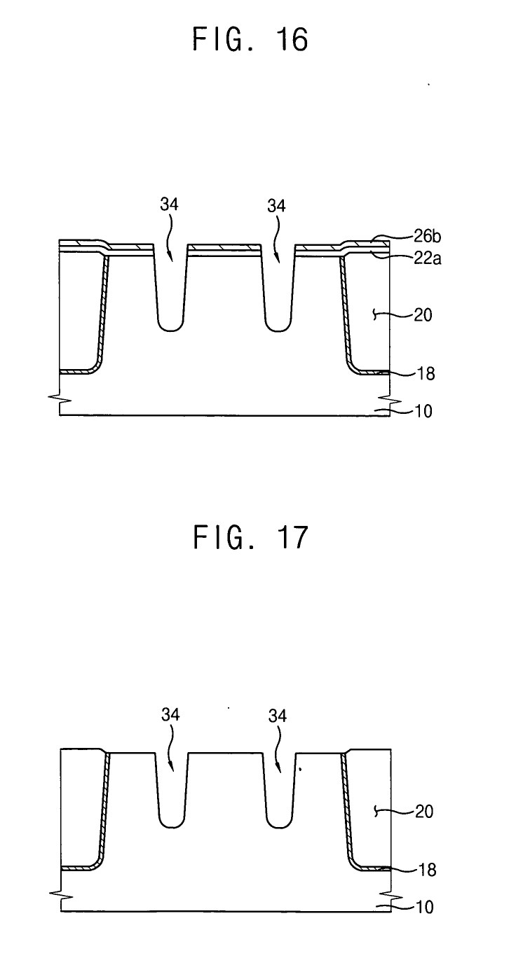

According to the above process, the active region in which the gate electrode is formed is partially exposed through the second hard mask pattern 30. Further, since the upper portion of the insulation liner 18a is partially recessed, the active region has an exposed sidewall. The first photoresist pattern 28 is then removed by ashing and stripping processes. Referring to FIGS. 9 and 16, the exposed active region is anisotropically etched using the second hard mask pattern 30 as an etching mask to form a gate trench 34. Here, the exposed sidewall of the active region as well as a planarized upper face of the active region is etched. Thus, the upper face of the active region is upwardly protruded in the etching process. In FIG. 9, dotted lines represent profiles of the gate trench by etching steps. As shown in FIG. 9, the exposed sidewall of the active region is firstly etched so that a portion of the active region adjacent to the field region is readily etched. Accordingly, although the active region is removed by a dry etching process causing a sloped profile of the gate trench, a silicon fence may not be formed between the active region and the field region. Further, the bottom face of the gate trench 34 has an upwardly protruded central portion in a direction substantially parallel to the gate electrode compared to an edge portion of the bottom face.

The protruded central portion of the gate trench 34 is caused by the recessed insulation liner 18a. Thus, the deeper the insulation liner 18a is recessed, the more the central portion is protruded. A protruded height of the central portion may vary in accordance with a recessed depth of the insulation liner 18a. In particular, the deeper the insulation liner 18a is recessed, the more the active region adjacent to the field region is readily etched. Therefore, the silicon fence may not be formed between the active region and the field region. As a result, to prevent the formation of the silicon fence in forming the central portion having an appropriately protruded height, the insulation liner 18a is recessed by an optimal thickness. Although, the recessed thickness of the insulation liner 18a may vary in accordance with the depth of the gate trench 34, the recessed depth of the insulation liner 18a is about 100 Å to about 500 Å.

In etching for forming the gate trench 34, the silicon oxynitride layer pattern 24b is also barely etched in accordance with an etching selectivity. As a result, when the etching process is completed, the silicon oxynitride layer pattern 24b having a thin thickness remains on the substrate 10.

Referring to FIGS. 10 and 17, a silicon fence after forming the gate trench 34 may partially remain on the side face of the gate trench 34. In such a case, a process for removing the remaining silicon fence may be additionally performed. The removal process may include a wet etching process or a chemical dry etching process, for example. When the remaining silicon fence is wet-etched, an etchant that is a mixture of NH₄OH, H₂O₂, H₂O, etc., may be used. The etchant may remove the semiconductor substrate 10, an oxide layer, an organic material, etc. The silicon oxynitride layer 24b and the MTO layer pattern 22a are removed by the above removal process. However, the insulation liner 18a exposed through the side face of the gate trench 34 is not removed by the removal process and remains.

As shown in FIG. 17, the semiconductor substrate 10 is exposed through the side face of the gate trench 34 except an interface between the gate trench 34 and the field region. When the silicon fence is removed, the exposed semiconductor substrate 10 as well as the silicon fence may be etched altogether. Particularly, since the removal process is carried out for a long time to entirely remove the silicon fence in accordance with a conventional method, the gate trench may have a relatively wide width so that the gate electrode may have a relatively wide width. On the contrary, according to the present embodiment, the silicon fence does not remain on the interface between active region and the field region after forming the gate trench 34. Therefore, the process for removing the silicon fence may be carried out for a very short time or may be omitted. In particular, when the silicon fence is removed by the wet etching process, the wet etching process may be performed for no more than about 10 minutes. As a result, the time for removing the silicon fence is reduced so that the gate trench 34 may have a relatively short length compared to the conventional method.

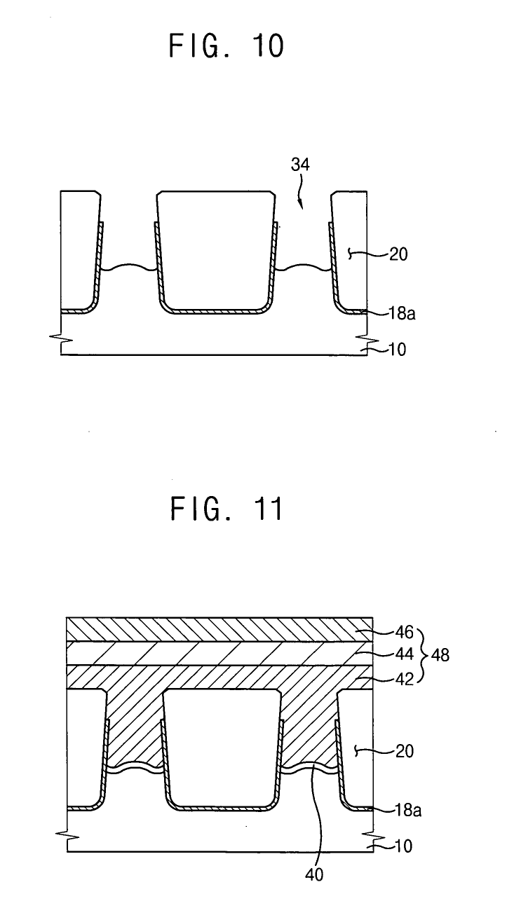

FIGS. 11, 18 and 20 are views illustrating a process for forming the gate electrode on the active region. Referring to FIGS. 11, 18 and 20, a gate insulation layer (not shown) is formed on the side face and a bottom face of the gate trench 34. The gate insulation layer may be formed by thermally oxidizing the substrate 10. When the gate insulation layer is formed by the thermal oxidation process, the gate insulation layer is selectively formed on portions of the substrate 10 exposed through the gate trench 34.

A polysilicon layer (not shown) is formed on the gate insulation layer to fill up the gate trench 34 with the polysilicon layer. A tungsten silicide layer (not shown) is formed on the polysilicon layer. A second silicon nitride layer (not shown) as a hard mask pattern is then formed on the tungsten silicide layer. A second photoresist film is formed on the second silicon nitride layer. The second photoresist film is patterned to form a second photoresist pattern (not shown) for forming the linear gate electrode. The second photoresist pattern covers the gate trench 34.

The second silicon nitride layer is etched using the second photoresist pattern as an etching mask to form a third hard mask pattern 46. The tungsten silicide layer and the polysilicon layer are patterned using the third hard mask pattern 46 to form the gate electrode 48 including a tungsten silicide layer pattern 44 and a polysilicon layer pattern 42. Here, the two gate electrodes 48 are formed in the single active region. The gate insulation layer is removed by a cleaning process to form a gate insulation layer pattern 40.

A silicon nitride layer (not shown) is formed on the gate electrode 48, the gate insulation layer pattern 40 and the semiconductor substrate 10. The silicon nitride layer is anisotropically etched to form a spacer 50 on sidewalls of the gate electrode 48 and the gate insulation layer pattern 40. Impurities are implanted into the active region at both sides of the gate electrode 48 to form source/drain regions 49. Here, the source/drain regions 49 have a bottom face higher than that of the gate trench 34.

An insulating interlayer (not shown) is formed on the gate electrode 48. Contract plugs 54 are formed in the insulating interlayer to make contact with the source/drain regions 49. A bit line 56 is electrically connected to the contact plug 54 electrically connected to the source region. A storage node contact 58 is electrically connected to the contact plug 54 electrically connected to the drain region. A capacitor is electrically connected to the storage node contact 58, thereby completing a DRAM device in accordance with the present embodiment.

According to the present embodiment, the DRAM device having the recessed channel transistor is manufactured. The channel region of the transistor is formed on the both side faces and the bottom face of the gate trench so that the length of the channel region is increased, thereby suppressing the short channel effect. Also, charges stored in the capacitor may not flow from the drain region to the source region so that the data retention time of the capacitor may be lengthened and also refresh characteristics may be improved.

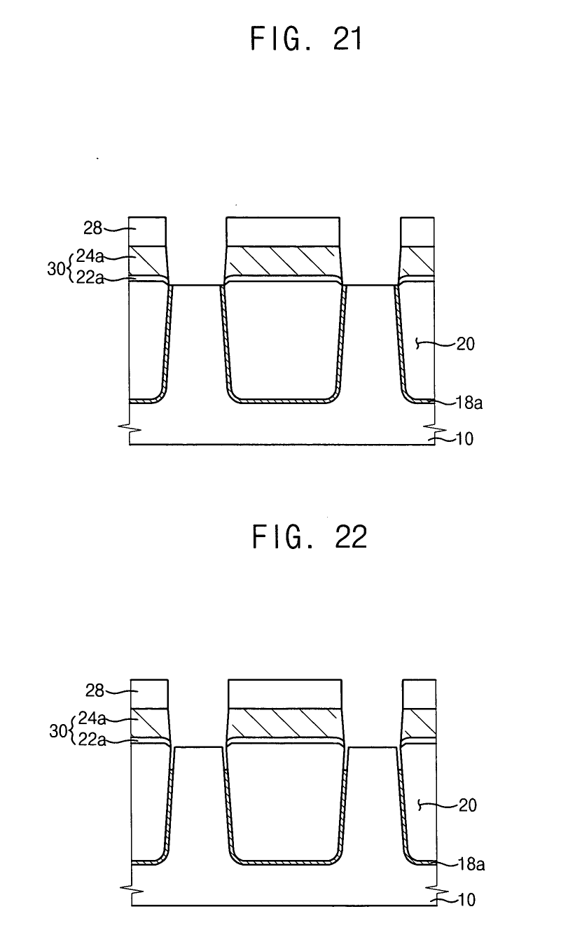

FIGS. 21 and 22 are cross sectional views illustrating a method of manufacturing the DRAM device of FIGS. 1 to 3 in accordance with a second embodiment of the present invention. A semiconductor device in accordance with the present embodiment includes elements substantially identical those in FIGS. 1 to 3. Thus, any further illustrations of the semiconductor device in accordance with the present embodiment are omitted. Also, same reference numerals refer to same elements. A method of manufacturing the semiconductor device in accordance with the present embodiment is substantially identical that in Embodiment 1 except for the processes of forming a hard mask pattern and an insulation liner. Processes illustrated with reference to FIGS. 4 to 6 are carried out to form a structure in FIG. 6. With reference to FIG. 21, a photoresist film is formed on the silicon oxynitride layer. The photoresist film is patterned to form a first photoresist pattern 28. The silicon oxynitride layer and the MTO layer are dry-etched using the photoresist pattern as an etching mask to form a second hard mask pattern 30 including an MTO layer pattern 22a and a silicon oxynitride layer pattern 24a. The second hard mask pattern 30 has a sloped sidewall. Thus, a portion of the active region exposed through the second hard mask pattern 30 has a width narrower than that of the photoresist pattern 30. After the etching process is carried out, the active region and a portion of the preliminary insulation liner 18 adjacent to the active region are exposed. Here, examples of an etching gas used in the etching process includes a mixed gas of CHF₃, CF₄, and O₂, a mixed gas of CH₂F₂, CF₄ and O₂, etc. Referring to FIG. 22, the exposed preliminary insulation liner 18 is partially recessed by a wet etching process to form an insulation liner 18. The insulation liner 18 has a recessed depth shallower than a depth of a gate trench. Processes illustrated with reference to FIGS. 9 to 11 and 16 to 18 are then performed to complete the DRAM device in FIG. 1.

According to the present invention, the formation of the silicon fence at the interface between the recessed gate electrode and the field region in forming the recessed gate electrode may be suppressed. Also, the top face of the gate trench has a relatively narrow width so that the recessed gate electrode has a relatively short length. As a result, a leakage current in the transistor may not be generated so that a highly integrated semiconductor device may be manufactured.

Having described the preferred embodiments of the present invention, it is noted that modifications and variations can be made by persons skilled in the art in light of the above teachings. It is therefore to be understood that changes may be made in the particular embodiment of the present invention disclosed which is within the scope and the spirit of the invention outlined by the appended claims.

1. An integrated circuit device, comprising:
a semiconductor substrate;
an isolation trench in a first portion of said semiconductor substrate;
an electrically insulating liner on a bottom and sidewalls of said isolation trench;
a field oxide region on said electrically insulating liner; and
a field effect transistor in said semiconductor substrate, said transistor comprising:
a gate electrode trench in a second portion of said semiconductor substrate;
a gate insulating layer lining a bottom and sidewalls of said gate electrode trench;
a gate electrode that extends in said gate electrode trench and contacts said electrically insulating liner and said gate insulating layer; and
source and drain regions extending in said semiconductor substrate and adjacent said gate electrode.

2. The device of claim 1, wherein said electrically insulating liner comprises silicon nitride; and wherein said gate insulating layer comprises silicon oxide.

3. The device of claim 1, wherein said gate electrode directly contacts said field oxide region.

4. The device of claim 3, wherein said gate insulating layer contacts said electrically insulating liner.

5. The device of claim 2, wherein said gate insulating layer contacts said electrically insulating liner.

6. The device of claim 5, wherein said gate electrode directly contacts said field oxide region.

7. The device of claim 1, further comprising a U-shaped capacitor electrode electrically coupled to said drain region.

8. The device of claim 1, wherein said drain region directly contacts said electrically insulating liner and said gate insulating layer.

9. A method of forming a recessed gate electrode comprising:
forming a field region including an isolation trench, an insulation liner formed on a side face and a bottom face of the isolation trench, and a field oxide layer filling up the isolation trench in the substrate to define an active region in the substrate;
forming a gate trench in the active region, the gate trench exposing an interface between the active region and the field region and having a bottom face and an opened top face wider than the bottom face; and
forming a gate electrode on the substrate and in the gate trench.

10. The method of claim 9, wherein forming the field region comprises:
forming the isolation trench at a surface portion of the substrate;
forming a preliminary insulation liner on a side face and a bottom face of the isolation trench;
filling the isolation trench having the preliminary insulation liner with the field oxide layer;
forming a first hard mask pattern that selectively exposes a region in which the gate electrode is formed and a portion of the preliminary insulation liner making contact with the region; and
partially etching the preliminary insulation liner using the first hard mask pattern as an etching mask to form the insulation liner having the upper end.

11. The method of claim 10, wherein the preliminary insulation liner comprises silicon nitride.

12. The method of claim 10, wherein the first hard mask pattern and the insulation liner are formed by performing a dry etching process once.

13. The method of claim 12, wherein forming the first hard mask pattern and the insulation liner comprises:
forming a pad oxide layer on the substrate;
forming an insulation layer on the pad oxide layer;
forming a photoresist pattern on the insulation layer; and
sequentially dry-etching the insulation layer, the pad oxide layer and the preliminary insulation liner to form the first hard mask pattern and the insulation liner.

14. The method of claim 13, wherein the preliminary insulation liner has an etching rate faster that of the pad oxide layer.

15. The method of claim 13, wherein the insulation layer, the pad oxide layer and the preliminary insulation layer are dry-etched using an etching gas mixed of CH₂F₂, CF₄ and O₂.

16. The method of claim 10, wherein etching the preliminary insulation liner is performed by a separate wet etching process.

17. The method of claim 10, wherein forming the gate trench comprises anisotropically etching a portion of the active region exposed through the insulation liner and the first hard mask pattern.

18. The method of claim 17, after forming the gate trench, further comprising removing a remaining first hard mask pattern.

19. The method of claim 10, wherein forming the gate electrode comprises:
forming a gate insulation layer on the active region and the gate trench;
forming a conductive layer on the gate insulation layer;
forming a second hard mask pattern on the conductive layer; and
etching the conductive layer and the gate insulation layer using the second hard mask pattern as an etching mask for exposing the surface of the substrate to form the gate electrode.

20. A method of forming a recessed gate electrode comprising:
forming a field region that partially exposes a side upper portion of an active region at an interface between the active region and the field region define the active region in the substrate;
etching a portion of the active region that includes the exposed side upper portion to form a gate trench exposing the interface between the active region and the field region;
forming a gate electrode on the substrate and in the gate trench; and
forming source/drain regions in portions of the active region at both sides of the gate electrode.

21. The method of claim 20, wherein forming the field region comprises:
forming the isolation trench at a surface portion of the substrate;
forming a preliminary insulation liner on a side face and a bottom face of the isolation trench;
filling the isolation trench having the preliminary insulation liner with the field oxide layer;
forming a first hard mask pattern that selectively exposes a region in which the gate electrode is formed and a portion of the preliminary insulation liner making contact with the region; and
partially etching the preliminary insulation liner using the first hard mask pattern as an etching mask to form the insulation liner having the upper end.

22. The method of claim 20, wherein the gate trench comprises a plurality of gate trenches in a single active region.

23. The method of claim 20, wherein the gate electrode comprises a linear gate electrode.

24. The method of claim 20, further comprising forming a capacitor electrically connected to at least one of the source/drain regions.

25.-32. (canceled)
